(19) United States
(12) Patent Application Publication
(10) Pub. No.: US 2018/0237945 A1
(43) Pub. Date: Aug. 23, 2018

(54) SPHERICAL DIAMOND AND MANUFACTURING METHOD FOR SAME

(71) Applicant: NANOCARBON RESEARCH INSTITUTE, LTD., Nagano (JP)

(72) Inventors: Eiji OSAWA, Nagano (JP); Ryouko YAMANOI, Nagano (JP)

(21) Appl. No.: 15/752,065

(22) PCT Filed: Aug. 10, 2015
(86) PCT No.: PCT/JP2015/072639

§ 371 Date: Feb. 12, 2018

(51) Int. Cl. C30B 29/04; C30B 29/66; B24B 9/16; B24B 11/02; B24B 37/02; B30B 3/00; B30B 9/28

(52) U.S. Cl. CPC C30B 29/04; C30B 29/66; B24B 9/16; B30B 9/28; B24B 37/02; B30B 3/005; B24B 11/02

(57) ABSTRACT

Among all the materials available on earth, diamond has demonstrated outstanding properties for general-purpose applications. Nevertheless, due to the total lack of processability, artificial diamonds have never captured large industrial markets for the recognized performance. However, theoretical chemists recently paid attention to an old but highly efficient way of producing new facets on gem diamonds by manual self-abrasion. They found by using molecular dynamics calculations that the rate-determining step in the self-abrasion sp³-sp² order-disorder transition on the crystal surface. The product of such a transition is an amorphous layer, which chemically decomposes to produce a new facet. Taking advantage of the self-abrasion mechanism thus found, we designed a novel spheroidization method and experimental apparatuses, wherein the self-abrasion works preferentially on mechanically weak portions like vertices and edges but hardly on stronger surfaces. Spherical diamonds lack self-aggregation properties, are resistant against shocks, have mechanically strong surface and offer a new material.

### FIELD OF TECHNOLOGY

This invention is concerned with a method of processing artificial single-crystal diamonds in order to promote and expand their industrial applications. More specifically it offers a new entry into the mass production of spherical diamond particles, which have high applicability for industrial uses. Whereas the method of spheroidizing diamonds to be disclosed below is considered valid to any size of diamond crystals, we will concentrate here on those smaller than mm sizes, especially micron-sized single-crystal diamond particles.

In general industrial materials are processed for specific purposes by using one of the three ways. One is to give physical deformation by using such inherent properties of material as thermal plasticity or optical hardening. The other way is to give chemical changes like sublimation, vaporization, melting, dissolution and chemical reactions. Still other way is to cut or polish by using other harder materials than the one under processing. However, diamond crystals do not accept any physical or chemical changes. In addition, as diamonds have the highest hardness and Young's modulus on earth, it is logically impossible to process them by abrasion with a harder material. For these reasons, the form of diamond at the end of its synthesis is destined to be the final form for application. Non-processability is the single reason why synthetic diamonds have so far found only very limited markets in their applications. Otherwise, synthetic diamonds would have been the most widely used material on earth.

### BACKGROUND TECHNOLOGY

However, one special technique has long been known for manipulating single-crystalline diamonds. It is called self-abrasion, wherein a diamond crystal is given strong collision or pressing with another diamond crystal to effect mutual abrasion. For example, a gem diamond crystal has been polished or cut by pressing it strongly against a disk studded with diamond grits and rotating at high speed in order to wear the contacting planes and cut out new facets having desired reflection angles. This method enables one to control the impact between colliding diamond crystals by adjusting the rotation speed of disc, and can be efficiently executed as experienced workers are able to locate readily wearable facets. This self-abrasion technique has been extensively used for machining gem diamonds in the past few centuries.

Atomistic mechanism of the hand polishing gem diamond by self-abrasion was recently elucidated by molecular dynamic calculations (Non-patent Literature 1). According to this work, the first step consists of sp³-sp² order-disorder transition that occurs when asperities on the surface of one diamond crystal collide with others. The transition produces amorphous sites at the point of contact. Repeated shocks on the amorphous portions cause large deformation to form chemically active spots which react with air oxygen to disrupt C—C bonds. Such oxidative decomposition ends up with rapid destruction of partial and eventually total destruction of asperities.

In the past self-abrasion has been used only for cutting out new surfaces on gem diamond crystals. However, if we generate weak but continuous collisions between rolling particles so that only the most vulnerable asperities like apexes and edges will become amorphous and decompose. If we keep rolling the diamond powder for a long time, the final product would be a mass of spherical diamond crystals. In view of the high efficiency in the self-abrasion process of gem diamonds, we may expect likewise fast production of large number of spherical diamonds in one continuous operation.

Spherical crystals have sometimes been observed among natural diamonds, but there is no precedence in the artificial single-crystalline diamonds. Spherical artificial diamonds are interesting in view of a large variety of applicative possibilities as mentioned below. Scientifically, spherical diamonds deviate from the definition of crystal (solid polyhedra surrounded by crystal planes), hence they can be considered as a new substance.

From practical point of view, the largest merit of spherical diamonds is the premise that they are free from aggregation. As the contact between a pair of perfect sphere involves infinitesimally small area, it cannot produce sufficient van der Waals interaction for aggregation to take place. This feature should appear eminently in spherical nanodiamond particles, which will flow like liquid, in sharp contrast to the polyhedral nanodiamonds, which are well-known for their high tendency to form strong interfacial agglutinates.

### PRIOR ART DOCUMENT

### Non-Patent Document

Non-patent literature 1, Pastewke, L.; Moser, S.; Gumbsch, P.; Moseler, M. Nature Mater. 2011, 10, 34-38.

### SUMMARY OF THE INVENTION

### Problems to be Solved by the Invention

If we regard the self-abrasion process, wherein diamond particles repeat strong collision among themselves, as a chemical reaction, it involves a large number of cleavage of strong C—C bonds, hence we cannot expect it to proceed readily. Therefore it is desirable to include as many powerful reaction-accelerating measures as possible, and apply them continuously. We found pressure and rolling effective. In addition, it is desirable to carry out such highly endothermic reactions as the cleavage of C—C bonds at high temperature.

In order to carry out self-abrasion, pressing and rolling simultaneously, technically the simplest way would be to place an appropriate amount of diamond particles between a pair of concentric disks, press the disks continuously against each other, and rotate the disks, most desirably in opposite directions. It is necessary to attach a circular wall along the periphery of lower disk, in order to prevent the rolling diamond particles from dropping off the edge. The construction of such an assembly resembles that of a stone mill.

When the spheroidization reaction was too slow, the mill may be heated by irradiating infrared ray. Conversely, if the abrasion proceeds too fast or the heat from the motor was too much, cooling would be necessary. However, we soon found that the abrasion reaction proceeds at readily controllable speed, hence neither heating nor cooling is not necessary.

We anticipate that the inner wall of our spheroidization apparatus in direct contact with diamond particles rotating and rolling at high speed will receive strong sliding friction from diamond particles to wear rapidly. Especially vulnerable will be the wall material made of steel, which forms iron carbides by the reaction with diamond surface and contaminate the substrate particles. It is therefore necessary to cover these walls with CVD diamond films. Incidentally we have been involved in the CVD homoepitaxial growth studies of polycrystalline diamond films by offering our 3 nm (or even smaller) diamond particles as the growth nuclei In the present preliminary testing stage, however, the time-consuming diamond-lining is omitted.

To summarize technical problems, we have five major factors that can be combined to design a practicable spheroidization apparatus for small diamond particles: self-ablation, pressing, rolling, temperature and lining. We will seek an optimum set of factors in order to complete our invention and achieve the goal.

In addition, the availability of starting material, the quasi-spherical artificial diamonds with various sizes, should be assessed. Artificial high-pressure high-temperature (HPHT) micro- to mm-sized diamonds are presently produced almost exclusively in China, and these are our primary sources of the raw material. When the production of HPHT single-crystalline diamond is taken over by China from the US and Europe, the price decreased to less than one-20″, thus offering a favorable situation for us.

### Means for Solving the Problems

Self-abrasion, pressure and rolling.

Technically, the simplest set-up to apply self-ablation, pressing and rolling simultaneously in one pot will be to place appropriate amount of diamond particles between a concentric and horizontally held pair of disks, and to rotate the lower disk, while the upper disk is fixed in parallel disposition and also working as a pressing weight (FIG. 1). Side wall is attached along the periphery of the lower disc to form a shallow cylinder with base. As the diameter of top disk was made smaller to loosely fit inside of the inner wall, it works as a cover and also as a weight. The cover and cylinder were cut out from a SUS plank with a lathe. This first-generation set-up looks similar to a stone mill.

The first version of spheroidization apparatus. We then adopted a commercial electric Chinese ink-stick grinder (FIG. 2 left) as the driving mechanism. Namely its circular ink stone was replaced by the above mentioned combination of cylinder-cover, while setting the cover and base disks horizontally by using the ink-stick holder (FIG. 2 center). However, it soon became clear that it is difficult to keep the horizontal disposition of cover and cylinder base simultaneously, hence a simple device was added to adjust the positioning of cover (FIG. 2 right). This second version of spheroidization apparatus proved workable and actually produced useful results as mentioned below. It should be added that a similar apparatus equipped with self-abrasion, pressing and rolling mechanisms as above may be designed by any experienced engineers, hence this invention is not restricted to the particular type mentioned herein.

Heating or cooling.

We first thought that the reaction chamber of cylinder-cover combination should be heated at 100-300° C., but the other parts including the motor and sensors (mentioned later) should better be kept at room temperature. These requirements produce additional problems of evaluating thermal resistance of the latter parts. In addition, lining with diamond film generate still other problem of the binding between the chamber material and CVD diamond film. Fortunately, we soon noticed that the self-abrasion proceeded at reasonable speed, hence we postponed the heat-resistance and other problems to a later stage of our work. However, the heating problem will recur when dealing with larger diamond particles in mm or cm sizes, when the abrasion time will be much longer than nano and micron sizes.

Diamond lining

Fortunately, CVD technology of producing high-grade diamond thin films is recently developing rapidly by using our dispersed 3 nm diamond particles as the homoepitaxial nucleation seeds, and already it is possible to produce polycrystalline diamond film having Young's moduli comparable to natural diamonds (Non-patent literature 2 and 3). We will also use Williams' method. The lining with other method and material should also be available, hence this invention is not restricted to the CVD diamond lining.

(Non-patent literature 2) 0. A. Williams et al., “Size dependent reactivity of diamond particles,” ACS Nano, 2010, 4, 4824-4830.

(Non-patent literature 3) 0. A. Williams et al., “High Young's modulus in ultrathin nanocrystalline diamond,” Chem. Phys. Lett., 2010, 495, 84-89.

We obtained apple-green colored HPHT single-crystalline microdiamond manufactured by Changsha Xinye Company, China, through an Importer New Metals & Chemicals Co., Tokyo, and used this material without further purification. As shown in a photograph (FIG. 3), taken by using a digital microscope (manufactured by HIROX Co., Tokyo, type KH3100), the HPHT diamond particles have quasi-spherical polyhedral shapes. Throughout this work, we took such microphotographs for every experimental batch, selected 120 to 500 isolated images of particles showing complete periphery without any overlapping with neighboring particles and derived Heywood diameter (that of a circle having equal area as the particle) and two-dimensional circularity index (4πS/p², where S means Heywood surface area, and p peripheral length, the index equals to 1 for a perfect circle), using a graphic analysis software MacView (purchased from Mountec Co., Tokyo). We compared average and divergence of these two parameters before and after self-abrasion operation and studied if there are significant changes to ascertain the progress of self-abrasion. We also drew histograms of appearance frequencies against Heywood diameters and circularity indices in each experiment in order to evaluate the characteristics of self-abrasion.

The above-mentioned single-crystalline microdiamond MMP had a nominal diameter of 22-36 μm and our analysis revealed a Heywood diameter of 29.15(5.65) μm and a circularity index of 0.78(0.10) (standard deviation given in parenthesis, the sample size 119).

### DETAILED DISCLOSURE OF THE PRESENT INVENTION

Four Examples will be given below from among 10 preliminary experiments carried out using the second version of our self-made spheroidization apparatus (FIG. 2 right, dimensions given in FIG. 4).

We start this section with presenting a successful case first. As the operation conditions of our apparatus were unknown at first, we set up an almost arbitrary set of operation parameters after only a few partial testing and began a full operation (see also Example 1). However, it soon became clear that the major motor responsible for the rotation of heavy abrasion cylinder evolved too much heat and external cooling with an electric fan proved insufficient. Hence the operation had to be suspended after six hours. After cooling to room temperature, the abrasion cylinder was opened and a few samples of microdiamond powder taken out from the central places of base disk. Even though there was no visible change except for somewhat darkened color, the powder sample was subjected to the shape analysis with the digital microscope and the graphic software. Results are shown in FIGS. 5 middle and 6 middle. Comparison of these histograms with those of pristine samples (FIG. 5 top and middle), respectively, revealed surprising changes. Distribution of Heywood diameters decreased as a whole: the central position shifted to a lower value by a few microns, and the distribution became unsymmetrical. Clearly a dynamic process of diminishing in size took place. In contrast, circularity index increased as a whole and considerable number of particles having circularity indices higher than 90% appeared after abrasion (FIG. 6 top and middle). Significance of the changes in these parameters before and after abrasion operation was studied by F- and t-tests (Table 1): F-tests confirmed equal dispersibility between the two groups, and t-tests revealed the difference statistically significant.

TABLE 1

| | | Circularity | Heywood |
|---|---|---|---|
| | Sample size | index | diameter, μm |
| Before | 119 | 0.78 (0.10) | 29.15 (5.65) |
| After 6 hours | 119 | 0.82 (0.09) | 26.73 (5.67) |
| t-test | dispersibility | equal | equal |
| p < 0.05(both | t (freedom) | 3.316 (236) | 3.286 (236) |
| sides) | p | 0.001 | 0.001 |
| | judgement | significant | significant |

As the result, we conclude a decrease of 8.3% in Heywood diameter and an increase of 5.1% in circularity, both significant.

Encouraged by the success, we carried out several more experiments. We soon noticed that failure in adjusting horizontal and vertical dispositions of cover and inner wall, respectively, leads to preferential destruction of microdiamond crystals (FIG. 7). More extensive destruction occurred when too high load was applied, and produced fragments centered at 14 μm in diameter (FIG. 8). The fragments constituted about one third of the whole particles. As the result, the average of Heywood diameter decreased by 17.7%, whereas circularity did not change. Destruction of diamond is supposed to have taken place when cleavage occurred more frequently than abrasion. However, too low load did not produce any change: Heywood diameter and circularity index after 12 hours of operation under otherwise identical conditions as in Example 1. It is hence absolutely necessary to control the load accurately. These failed cases are not included in Examples.

We observed the following interesting phenomenon while continuing preliminary experiments under different conditions. After fine-adjusting relative position of cylinder and cover, a long operation was carried out for five days under the same conditions as in Example 1. Surprisingly enough, average diameter increased and circularity decreased slightly. Careful examination of the processed particles under digital microscope revealed considerable number of plate-like particles up to 50 μm to have been formed (FIG. 9). Thus, we found that our self-abrasion process could sometimes produce large deformations like flattening in diamond particles, and present the following interpretation.

We suspect that the microdiamond used here contains certain amount of poor crystals having excessive lattice defects. Defective crystals are considered to have larger size and smaller density than good crystals due to extra space within the lattice. Closer look at the diameter distribution before self-abrasion indicates a small peak at a diameter of 40μin, which supports the flattening assumption (FIG. 5 top). If we further assume that particles larger than 37.5 μm in diameter are defective crystals, they occupy 9.32 vol % of the whole particles. As the artificial HTHP diamonds are grown in very short time, we cannot exclude the possibility of contamination with poor crystals.

The major peak in the circularity histogram before abrasion appears at a circularity of 82%, which does not coincide with the average circularity of 78% (FIG. 6 top). The shift of average is likely to have been caused by wide distribution of low-circularity particles in 40-70% range. These low-circularity particles are most likely rod-shaped, as often seen in the digital microscope images of microdiamonds before abrasion treatments (FIG. 3), and correspond to the above mentioned particles populating in the left region of FIG. 6 top and also to the large and coarse particles centered at 40 μm in the Heywood diameter histogram (FIG. 5 top).

The low-circularity particles almost completely disappeared in the spheroidized microdiamonds as shown in FIG. 6 middle and bottom. Thus, we may conclude that ill-shaped and poorly balanced particles must have been quickly corrected in the course of abrasion, if they can roll. However, if the rod-shaped particles are present, they cannot roll to avoid large collisional energy under pressure and undergo deformation into plate-like crystals. The rod-like crystals tend to increase deformation under the same condition and will decrease in the average circularity, hence the changes in circularities cancel each other. This consideration explains the reason why circularity did not noticeably change after long self-abrasion.

When plate-like diamond crystals are spread on a slide glass under microscope, they tend to take a flat position with the largest facet on its back, and look larger than real. FIG. 9 shows such dispositions of crystals larger than 50 μm.

In the course of long processing time, during which the ill-shaped particles developed plate-like deformation, well-shaped particles undergo self-abrasion and increase their circularities. Nevertheless, the increments in circularities are cancelled by the decreased circularities due to the flattening of ill-shaped particles in the averaging. As the result the average circularity did not change.

How would the Heywood diameter be affected by the appearance of flattened particles? As we look down the slide glass from above, the size of flattened crystals are overestimated. Small peaks of large Heywood diameters on the right side of histogram in FIG. 6 bottom between 45 and 52.5 probably correspond to the overestimated flattened crystals.

The results obtained by preliminary experiments on the second version of self-abrasion apparatus are summarized as follows:

(1) Interparticle interactions between microdiamond crystals taking place in our self-abrasion apparatus under pressure are much stronger than expected, and we conclude that spheroidal diamonds can be prepared on macroscopic scale in relatively short time (like overnight).

(2) A large number of factors must be rightly optimized simultaneously in order to suppress cleavage, deformation and other damages on diamond crystals.

(3) Self-abrasion apparatus must be equipped with high-precision measurement devices for rotational speed of cylinder, horizontal suspension and pressure from load.

(4) The pressure gauge for the load is the most important tool to achieve high sphericity. Optimum condition may be dependent upon the size of diamond particles.

(5) Quality of artificial single-crystalline diamond is likewise important. Especially noteworthy is to exclude particles with larger diameters and abnormally small sphericities. For these purposes, histograms of Heywood diameters and circularity index are useful.

### EFFECTS OF THE INVENTION

Spherical diamonds are much more useful industrial material compared to the conventional defective polyhedral diamonds. In the former, crystal facets are not fully exposed, hence cleavage hardly occurs. It uses only small area in contact with neighboring matter, hence wear is correspondingly less. For the same reason, self-aggregation rarely happens. The last-mentioned effect is expected to appear most profoundly in nanodiamonds.

The self-abrasion method of manufacturing spherical diamond as presented in the present invention can be in principle applied to any sizes of artificial diamonds. Applications are especially wide for the mm-sized spherical artificial diamonds. For example, replacements of steel balls in the ball bearings, artificial gems, ball-shaped lenses, ball for the ball-point pens, and spherical semi-conductors are all promising (Non-patent literature 5). Spherical diamonds are indispensable for the optical lenses to be used in the night eye-glasses and telescopes carrying an infrared sensor. Extensive demands are expected for military uses and night-driving.

(Non-patent literature 5.) “Stories on spheres (in Japanese)” Shibata, J., Gihodo Publishers, 2011, pp. 166.

The primary motivation for this invention was to produce spherical nanodiamonds, which can be used as spacers in the non-oil lubrication (Patent literature 1, 2). Still now this is the primary purpose of this invention. The spacer lubrication is the most reasonable replacement of oil lubrication, a ‘necessity evil’ in the modern technology. We have been erroneously using oil as lubricant for too long time. If we use spherical artificial single-crystalline nanodiamond particles as spacers in lubrication, we may expect superlubrication with virtually zero frictional constant, drastic reduction in fuel cost, and concomitant suppression of CO₂-emission. The improved lubrication will eventually contribute to slowing down the warming of earthen weather.

(Patent literature 1). “Nanospacer lubrication (in Japanese),” WO/2012/029191, Publication patent 2013-538274, Inventors E. Osawa, and S. Mori.

(Patent literature 2.) Nanospacer lubrication (in English),” International application No.: PCT/JP2010.065671, International Filing Date: 03.09.2010, Priority Date: 03.09.2010, Publication No.:WO/2012/029191, Publication Date: 2012.03.08. Applicants/Inventors: NCRI, OSAWA, Eiji, MORI Shigeyuki.

### BRIEF DESCRIPTION OF THE DRAWINGS

FIG. 1 Illustration showing basic concept of combined pressing, rolling and self-abrasion actions. A layer of diamond particles is inserted between a pair of hard and concentric disk. Disks are pushed toward each other, so that all the particles make close contacts with neighboring particles. At the same time, the two disks are rotated in opposite direction in order for the whole diamond particles to engage in rolling.

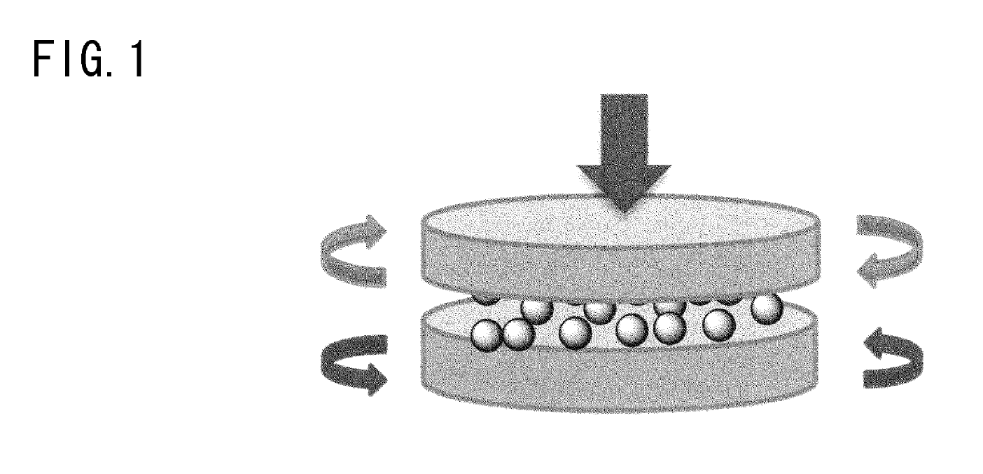

FIG. 2 Left: A commercial motor-driven Chinese ink-stick grinder. A shallow circular ink-stone is filled with water and revolved slowly, and a pair of ink-stick are fixed to holders by screwed pinches and pressed vertically onto the revolving ink-stone. Used for producing fresh aqueous ink for calligraphy. Center: The first version of spheroidization apparatus. Shallow and circular ink-stone is replaced by a shallow cylinder with a base disk with 103 mm in the inner diameter, 30 mm in depth and 6 mm in thickness, made of SUS 304, and fixed to the ink-stone motor, and revolved at a rate of about 30 rpm. At the bottom of cylinder is spread 20 g of microdiamond powder. A SUS 304 cover disk with a diameter of 100 mm, a thickness of 5 mm, a weight of 620 g, is inserted into the cylinder. The cover disk also works as a weight (see FIG. 4). Right: The second version of spheroidization apparatus. A simple device that is able to adjust the positioning of cover disc is attached at the right end of apparatus. In addition, the original plastic shield was removed to assist external cooling by means of an electric fan and avoid overheating.

FIG. 3 A digital microscopic image of microdiamond before spheroidization. Nominal diameter of diamond powder=22-36 μm. Microscope is manufactured by Tokyo Hirox Co., Type KH1300.

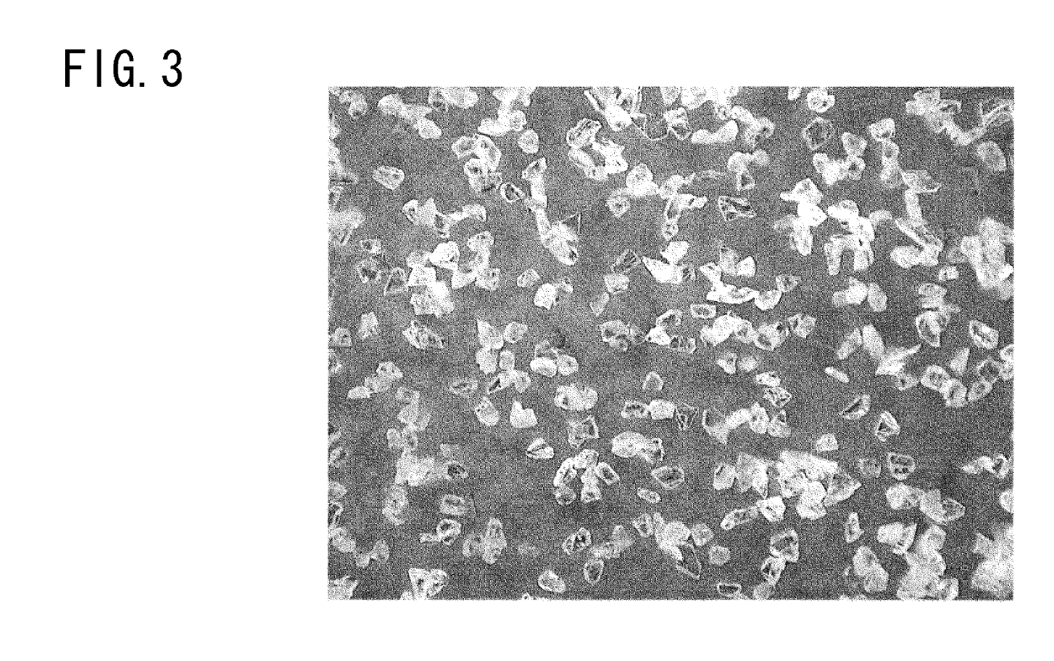

FIG. 4 Dimensions of the first version of spheroidization apparatus in mm.

FIG. 5 Histogram of Heywood diameter distribution in microdiamond at various stages of spheroidization process. Top: Before abrasion (sample size=119). Middle: After execution of Example 1 (sample size=119). Bottom: After completion of Example 4 (sample size=512).

FIG. 6 Histogram of circularity index distribution in microdiamond at various stages of spheroidization process. Details are same as FIG. 5.

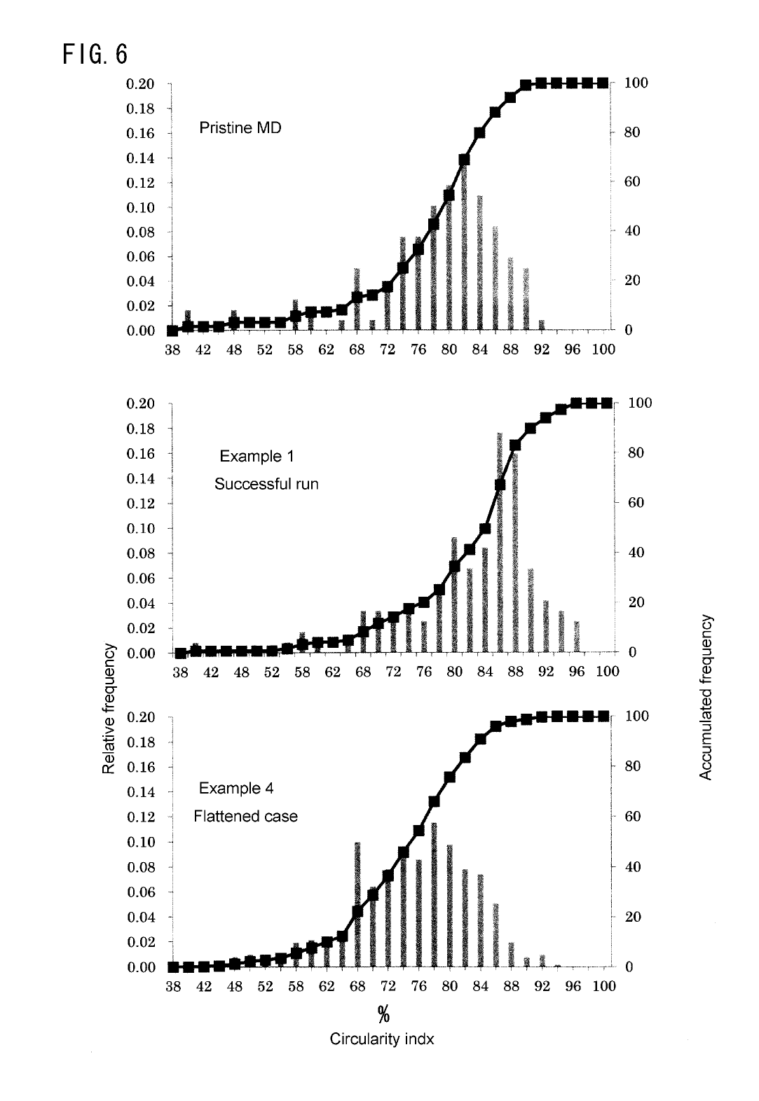

FIG. 7 A digital microscopic photograph of microdiamond after the completion of Example 2. Note the pulverized layer of microdiamond particles.

FIG. 8 Comparison of the distribution in Heywood diameters of microdiamonds before spheroidization and after the completion of Example 2. About 30% of the whole sample became pulverized to reduce the average diameter from 29.15±5.65 μm before abrasion to 23.98±7.34 μm. No significant change was observed in circularity index.

FIG. 9 Digital microscopic photographs of flattened microdiamond particles after the completion of Example 4.

### EMBODIMENTS OF THE INVENTION

The present invention can be better understood by reading the following explanations while looking at the Figures. Although individual details are given in Examples, this invention is not limited to the particular methods, conditions, devices and illustrations mentioned below.

### EXAMPLE 1

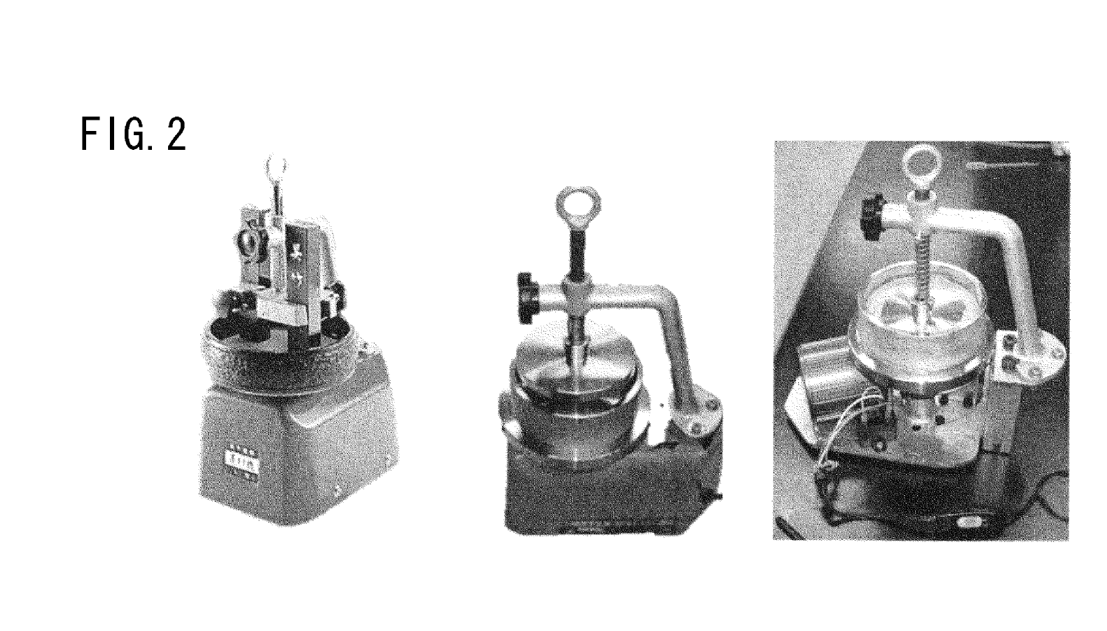

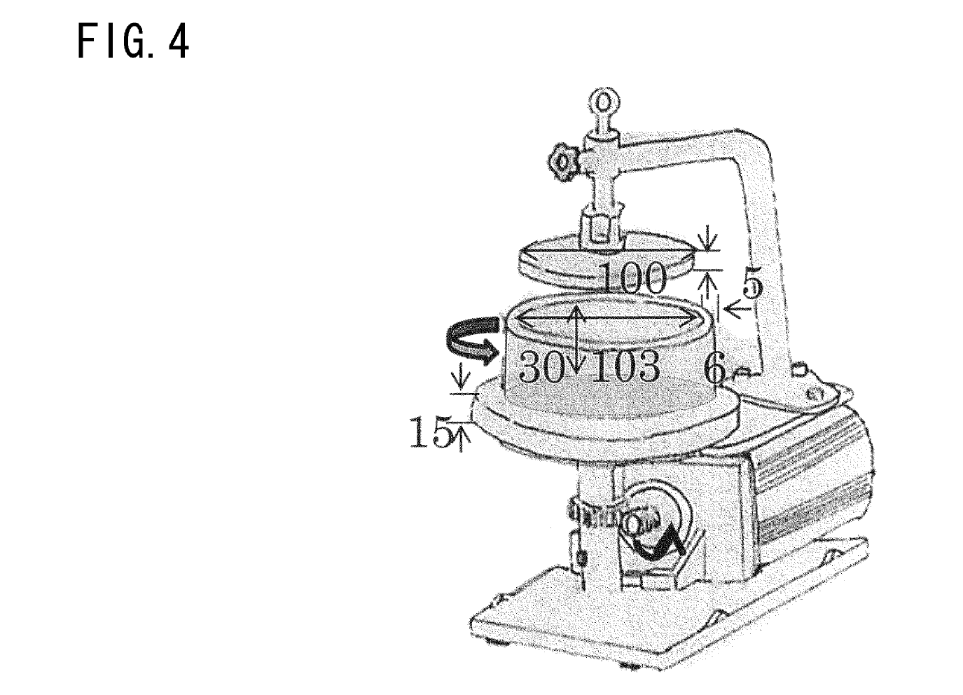

The ink-stone revolving mechanism of a commercial Chinese ink-stick motor grinder (FIG. 2 right) was removed and a SUS304 self-abrasion cylinder with an inner diameter of 103 mm, a depth of 30 mm and a thickness 6 mm was attached as shown in FIG. 4. In addition, the ink-stick holding mechanism was replaced with a SUS304 disk with a diameter of 100 mm, thickness 5 mm and a weight of 620 g, which was slid horizontally into the inside wall of abrasion cylinder, thus acting as a weight as well as cover. The modified set-up is called here as the second version of spheroidization apparatus. Twenty g of commercial microdiamond powder having an average diameter of 29 μm was placed in a thin space between the cover and bottom disc of the abrasion cylinder, which was then subjected continuous revolving by turning on the motor. However, the motor proved too small to drive heavy cylinder for a long time, and evolved much heat. When the temperature of outer wall of cylinder reached 70° C. after six hours, the operation was suspended.

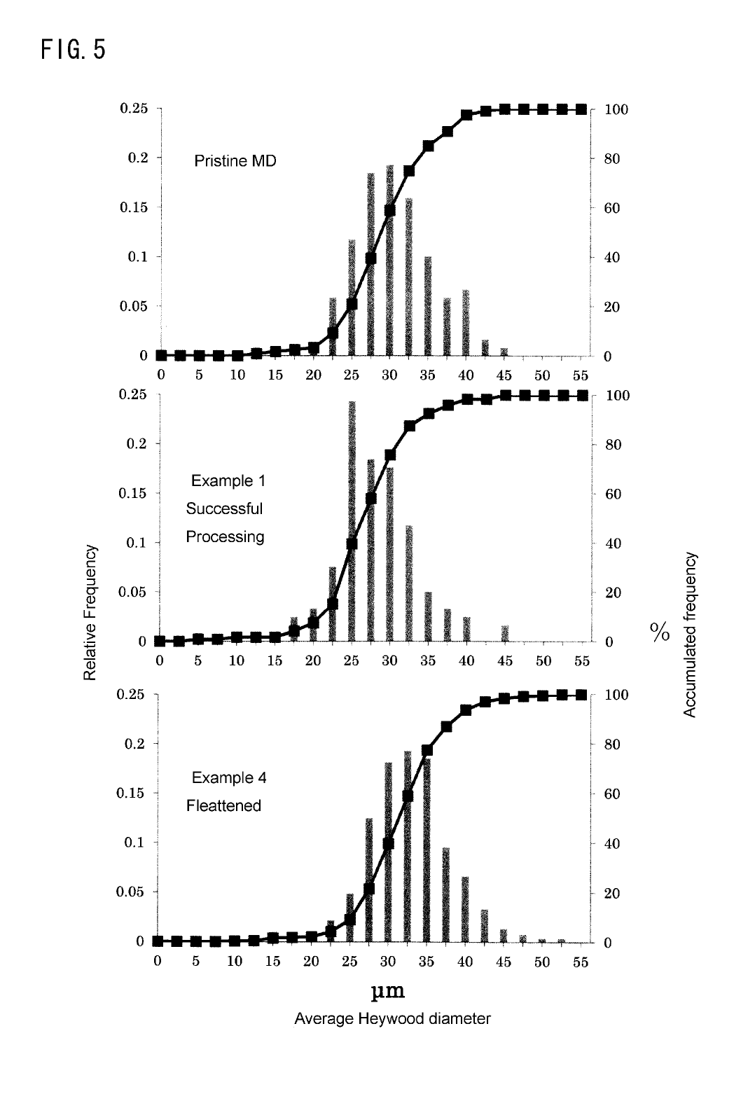

After leaving the spheroidization apparatus to room temperature, a few portions of abraded microdiamond were sampled from near the center of cylinder bottom and observed under a digital microscopy (constructed by Tokyo HIROX Co., Type KH3000). In the beginning no visible change could be discerned except for slightly darkened color of the particle surface, but 119 isolated particles that showed continuous periphery were selected under the microscope and subjected to the analysis of Heywood diameters and circularity index using commercial image analysis software (MacView, 4^{th} Version, from Tokyo Mountech Co.). Comparison of histogram distribution of these parameters before and after the spheroidization operation revealed much difference (FIGS. 5 & 6): Heywood diameters decreased whereas circularity index increased. In the latter a few new peaks having circularity indices higher than 90% appeared. As these shifts were much smaller than the distribution widths, significance of the changes was studied by F- and t-tests. The changes in both parameters before and after self-abrasion proved to have equal dispersibility and siginificant difference, respectively (Table 1). Results of statistical analysis are described in the previous section DETAILED DISCLOSURE OF THE PRESENT INVENTION.

### EXAMPLE 2

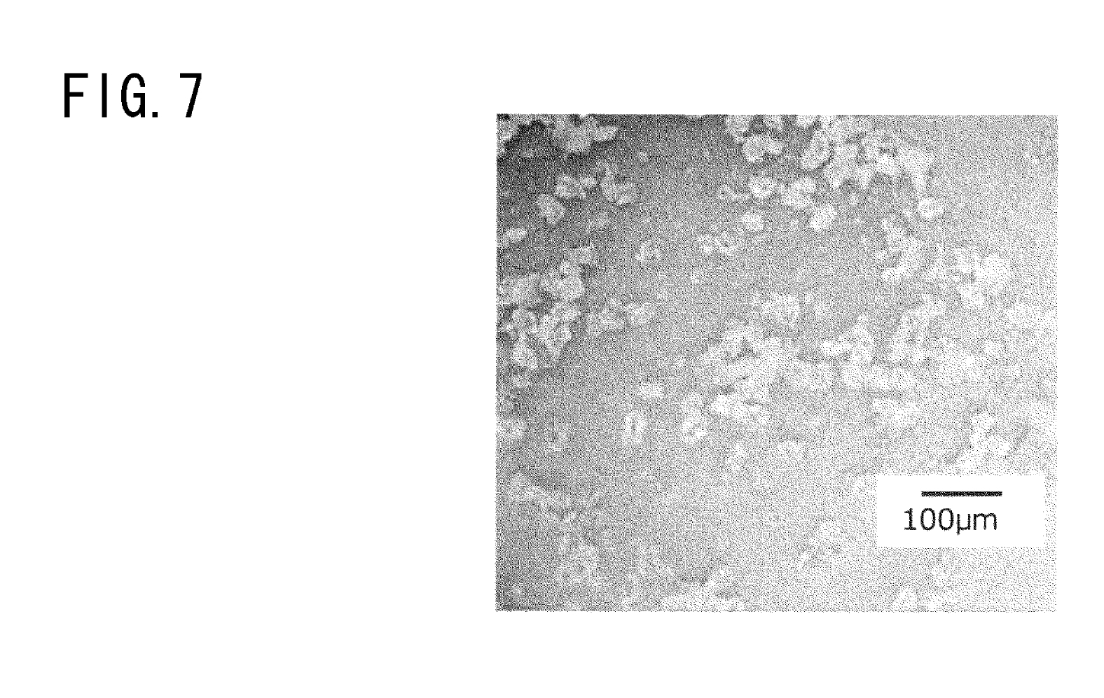

Using the same spheroidization apparatus as mentioned above, we managed to hang the heavy cover in exactly parallel position with the base of cylinder to avoid excessive friction between them and suppress heat evolution to allow longer and continuous operation. In the course of adjusting and running, we had a bad case of direct and strong contact between cover and base disks, which kept revolving for a few hours making sharp noise. Abraded microdiamond powder had developed intense black color, indicating contamination of SUS304 from the inner wall. Inspection under the digital microscope showed a large proportion of pulverized microdiamond particles (FIG. 7).

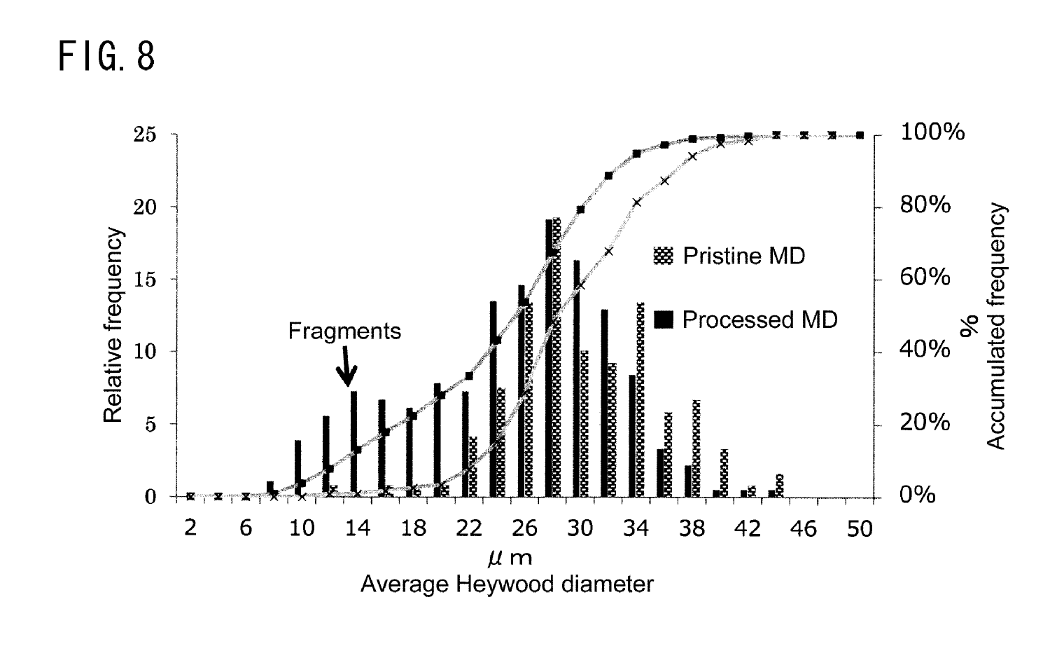

We sampled 177 pieces of microdiamond randomly and analyzed the distribution of Heywood diameter (FIG. 8). The histogram showed that about one third of the powder was fragmented into much smaller pieces and formed a second broad distribution centered at 14 μm in diameter (FIG. 8). The rest comprises the major peak at the same position as before the abrasion. Namely, fragmentation preceded abrasion when too high pressure was applied.

### EXAMPLE 3

In contrast to Example 2, we encountered with an opposite result, wherein neither Heywood diameter nor circularity coefficient changed significantly before and after 12 hours of continuous operation. The t-Test confirmed this conclusion of no change. Although we did not measure the pressure, it seems that in this case the applied pressure was out of range. It is likely that the applied pressure was somewhat lower than the critical value. We will take advantage of this lesson in the design of the third and higher models in order to realize the desired spheroidization.

### EXAMPLE 4

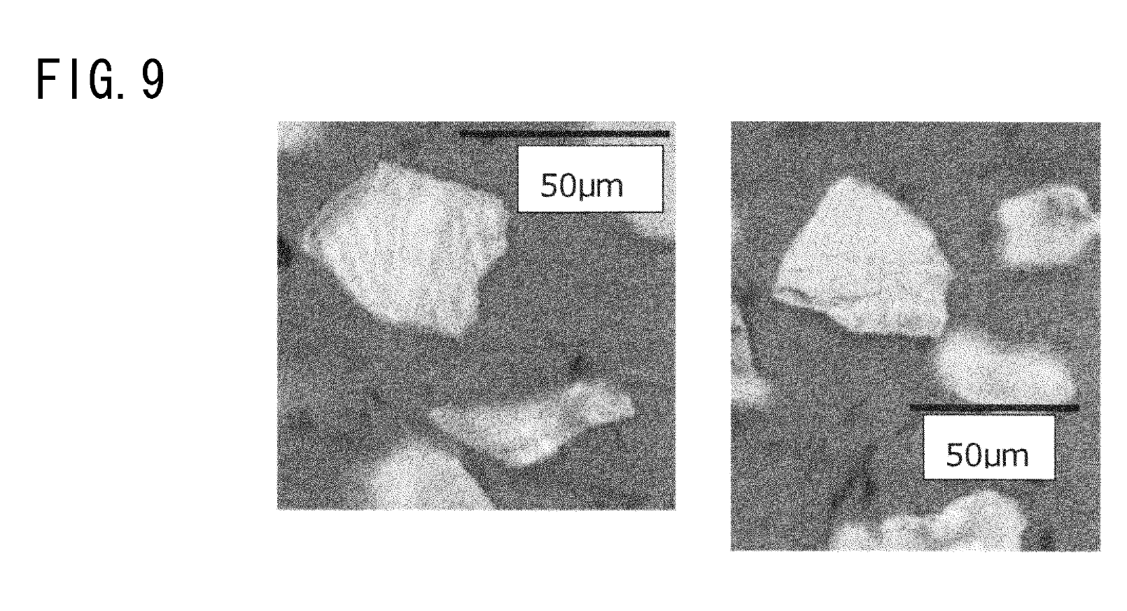

In another experiment in which we wanted to reproduce and extend the results of Example 1, we encountered still different result. After the most careful adjustments of the parallel disposition between cover and base disks, we succeeded in running the abrasion continuously for five days. However, the results were surprising: diameter increased and circularity decreased, both by small margins. Furthermore, observation under the digital microscope revealed extremely large particles with diameters up to 50 μm and remarkably flattened in shape (FIG. 9). The interpretation of these observations was given in the section DETAILED DISCLOSURE OF THE PRESENT INVENTION in great detail.

We have demonstrated various possibilities of manipulating shapes of small diamond particles by means of pressure- and rolling-assisted self-abrasion method, with special attention to the spheroidization which should add much higher value to the small artificial diamond particles for industrial applications. However, this invention is not limited by the few examples given here, but should give many more variations in the shapes of diamond within the claimed scope of invention.

1. A method of manufacturing spherical diamond particles by subjecting irregular polyhedral single-crystalline diamond powder to an improved spheroidization process, wherein asperities on the crystal surface like apexes and edges are preferentially abraded upon light but direct collision with the neighboring diamond particles to approach spherical surface morphology.

2. A method of manufacturing spherical diamond particles as mentioned in claim 1 but characterized by controling the spheroidization process of self-abrasion using one or a plural number of the following four auxiliary measures including (1) pressing, (2) rolling, (3) heating or cooling, (4) lining of the inner wall of the cylindrical abrasion container with CVD polycrystalline diamond thin-film.

3. Spherical diamond particles manufactured as described in claim 2, each particle consisting of the known internal diamond core and spherical surface comprising of a large number of partial facets. The particles are further characterized by appropriately high sphericity index, or circularity index derived from the analysis of two-dimensional images. When the spherical diamond particles are smaller than micron sizes, it is desirable that they have circularity index of greater than 90%, or more favorably greater than 95%.

4. Spherical diamonds as described in claim 3, and characterized by having the unsaturated valence of surface carbon atoms formed by the abrasion process saturated by adding hydrogen, fluorine, oxygen, water and other substances.

5. Manufacturing method of spherical diamonds as described in claim 2, and characterized by adopting the pressing process, one of the auxiliary processes claimed to accelerate the spheroidization, in the following manner. Vertical pressure is created by weights placed on top of the cover disk and applied to a layer of single-crystalline diamond particles, loosely packed in the abrasion cylinder in such a way that each particles can be readily roll with the revolving movements of cylinder. Such an arrangement works to increase the force acting between asperities on the surface of diamond particles in direct or shearing contacts to accelerate their destruction by wearing.

6. Manufacturing method of spherical diamonds as described in claim 2, but characterized by adopting the rolling process, one of the auxiliary processes claimed to accelerate the spheroidization, in the following manner. In this invention, rolling is introduced in order for spheroidization to occur evenly over the entire surface of diamond particle to reach the desired high sphericity in the shortest possible operation time. This purpose is fulfilled by horizontally revolving the cover and cylinder of self-abrasion apparatus in opposite directions or revolving only the cylinder and fixing the cover at a static configuration. In this way all the diamond particles always keep rolling to achieve uniform abrasion of surface and reach high sphericity.

7. Manufacturing method of spherical diamonds as described in claim 2, but characterized by adopting the heating or cooling, one of the auxiliary processes claimed to accelerate the spheroidization, as mentioned above, in the following manner. In this invention, heating is introduced in order to accelerate the spheroidization reaction by heating the space of self-abrasion chamber to 100 to 300° C., or cooling is introduced in order to retard the reaction by cooling the same space to below room temperature, with the purpose of reaching the desired sphericity in the shortest possible operation time.

8. Manufacturing method of spherical diamond as described in claim 2, and characterized by adopting lining of the inner wall with high-quality polycrystalline diamond film, one of the auxiliary methods of accelerating the spheroidization, namely, as follows. In this invention, the purpose of lining is to prevent wearing damage of inner wall by collision with the diamond particles being abraded. Especially vulnerable material of inner wall will be iron, which will form brittle iron carbides. We will use readily available 3 nm diamond particles as the nucleation seeds for the lining with polycrystalline CVD diamond film.
